(19) United States
(12) Patent Application Publication
(10) Pub. No.: US 2007/0215966 A1
(43) Pub. Date: Sep. 20, 2007

(54) Piezoresistance element and semiconductor device having the same

(75) Inventor: Naokatsu Ikegami, Saitama (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD, Tokyo (JP)

(21) Appl. No.: 11/649,217

(22) Filed: Jan. 4, 2007

(30) Foreign Application Priority Data
Mar. 16, 2006 (JP) 2006-72750

(51) Int. Cl. H01L 29/82; H01L 29/84

(52) U.S. Cl. 257/419; 257/414

(57) ABSTRACT

A piezoresistance element formed in a semiconductor substrate, includes a pair of contact regions formed in the semiconductor substrate; a groove formed between the pair of contact regions; a resistance layer formed in the groove, the resistance layer having a conductive type opposing to the semiconductor substrate; and a silicon layer formed on the resistance layer, the silicon layer having a conductive type corresponding to the semiconductor substrate.

### CROSS REFERENCE TO RELATED APPLICATION

This application claims the priority of application No. 2006-72750, filed on May 16, 2006 in Japan, the subject matter of which is incorporated herein by reference.

### TECHNICAL FIELD OF THE INVENTION

This invention relates to a structure of a piezoresistance element and a semiconductor device having the same.

### BACKGROUND OF THE INVENTION

In recent years, a micro structure, which is a small in sized of hundreds micron meters, has been an object of public attention in the semiconductor manufacturing field. Such a micro structure is fabricated using a micro-machine technology, which is an application of semiconductor fine processing technology. A micro structure has been considered to be applied to a high-frequency device, including sensors and optical switches for optical communication. In general, a microstructure based on a micro-machine technology is fabricated using a semiconductor process, so that such a device can be integrated on a semiconductor chip together with a LSI for signal processing. Such a device is called “MEMS (Micro Electrical Mechanical System)” in the USA and “MIST (Micro System Technology)” in Europe.

An acceleration sensor can be fabricated using MEMS (MIST) technology. An acceleration sensor has been widely used for an airbag system of vehicle; a subsurface environment observation system for seismic activity; a seismic system for IT products; and so on. Japanese Patent Publication No. H07-225240A describes a piezo-type of acceleration sensor using MEMS technology.

### [Patent Related Publication 1] JP H07-225240A

Conventionally, it is known that a piezoresistance element may be formed on a semiconductor substrate by the following methods:

(1) According to a conventional method, impurities are added to a semiconductor substrate by an ion implantation process or diffusion process to form a resistance layer on a surface of the semiconductor substrate.

(2) According to another method, a first impurity-diffused layer having a first conductive type is formed on a surface of a semiconductor substrate and a second impurity-diffused layer having a second conductive type, which is the opposite to the first conductive type, is formed on the first impurity-diffused layer to form a buried resistance layer in the semiconductor substrate.

(3) According to still another method, as shown in Japanese Patent Publication No. H07-131035A, dopant having a conductive type, for example p-type, opposing that of a semiconductor substrate, for example n-type, is ion-implanted at a high energy, for example 1 MeV, into the semiconductor substrate, so that a buried resistance layer is formed in the semiconductor substrate. At this time, the conductive type of the surface of the semiconductor substrate is maintained during the process.

### [Patent Related Publication 2] JP H07-131035A

However, according to the above-describe method or technique (1), the resistance layer is located at an upper surface of the semiconductor substrate, so that a resistive value of the resistance layer may be changed undesirably due to external electric field (surface-electric-field effect).

According to the above-described method or technique (2), a resistance layer is buried in a semiconductor substrate, so that a negative reaction due to an external electric field is reduced. However, since impurities are diffused twice in the semiconductor substrate, high-density diffused layers are coupled to each other and a breakdown voltage is lowered. As a result, noises are increased due to leak current.

According to the above-described method (3), a MeV (Mega-Volt) level of high energy ion-implantation is carried out, so that a crystal defect is formed on a silicon surface. Such a crystal defect could be recovered in a following thermal treatment to some extent, but could not be recovered completely. A defect due to a fabrication process may decrease or weaken mechanical strength of beams, on which piezoresistance elements are formed. Further, a vibrational lifetime of the sensor may be shortened, and product reliability may be decreased. Such disadvantages are described in the article of “Microelectronics Reliability 1 (2001) 1657-1662” or “Sensors and Actuators A 10 (2004) 150-156”.

### OBJECTS OF THE INVENTION

Accordingly, a first object of the present invention is to provide a piezoresistance element, in which a resistance value thereof is hardly changed due to an external electric field.

A second object of the present invention is to provide a piezoresistance element, which has a high breakdown voltage and a less amount of leak current.

A third object of the present invention is to provide a piezoresistance element, which has improved mechanical strength, a longer vibration lifetime and higher product reliability.

A fourth object of the present invention is to provide a semiconductor device including a piezoresistance element, in which a resistance value thereof is hardly changed due to an external electric field.

A fifth object of the present invention is to provide a semiconductor device including a piezoresistance element, which has a high breakdown voltage and a less amount of leak current.

A sixth object of the present invention is to provide a semiconductor device including a piezoresistance element, which has improved mechanical strength, a longer vibration lifetime and higher product reliability.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention, a piezoresistance element formed in a semiconductor substrate, includes a pair of contact regions formed in the semiconductor substrate; a groove formed between the pair of contact regions; a resistance layer formed in the groove, the resistance layer having a conductive type opposing to the semiconductor substrate; and a silicon layer formed on the resistance layer, the silicon layer having a conductive type corresponding to the semiconductor substrate.

According to a second aspect of the present invention, a semiconductor device having a piezoresistance element, which includes a pair of contact regions formed in the semiconductor substrate; a groove formed between the pair of contact regions; a resistance layer formed in the groove, the resistance layer having a conductive type opposing to the semiconductor substrate; and a silicon layer formed on the resistance layer, the silicon layer having a conductive type corresponding to the semiconductor substrate.

According to another aspect of the present invention, a method for fabricating a piezoresistance element includes: forming a groove on a semiconductor substrate; forming a resistance layer in the groove to have a conductive type opposing to the semiconductor substrate; and forming a silicon layer on the resistance layer to have a conductive type corresponding to the semiconductor substrate.

The silicon layer may be of a polycrystal layer. The resistance layer may be a buried impurity-diffusion layer, formed by an ion implantation process of boron (B). The groove may be formed by a wet-etching process.

Preferably, the above-described method for fabricating a piezoresistance element further includes a step for forming a pair of contact regions by an ion implantation process, in which the contact regions are located at areas corresponding to contact holes. The groove is formed between the pair of contact regions.

According to still another aspect of the present invention, a method for fabricating a semiconductor device including a piezoresistance element, which is fabricated by a method including the steps of forming a pair of contact regions by an ion implantation process, the contact regions being located at areas corresponding to contact holes; forming a groove between the pair of contact regions; forming a resistance layer in the groove to have a conductive type opposing to the semiconductor substrate; forming a silicon layer on the resistance layer to have a conductive type corresponding to the semiconductor substrate; and forming a wiring connected to the contact regions.

The silicon layer may be of a polycrystal layer. The resistance layer may be a buried impurity-diffusion layer, formed by an ion implantation process of boron (B). The groove may be formed by a wet-etching process.

According to the present invention, a resistance layer is formed in a groove and a silicon layer is formed on the resistance layer, in which the silicon layer has a conductive type corresponding (identical) to the semiconductor substrate and the resistance layer has a conductive type opposing to the semiconductor substrate. The resistance layer is buried in an upper surface of the semiconductor substrate, so that a resistance value of the resistance layer is prevented from being changed due to external electric field. An impurity density above the buried resistance layer can be suppressed. As a result, a breakdown voltage becomes higher and a leak current becomes lower, as compared to a conventional technology using a double diffusion process of impurity. In addition, a resistance layer is formed on an exposed surface of a semiconductor substrate, so that crystal characteristic of the resistance layer may be improved.

If a silicon layer, formed on a resistance layer, is of a polycrystal layer, amount of crystal defect in the silicon layer would be decreased. Further, the silicon layer would have a higher mechanical strength, which is similar to a single crystal, so that a longer vibration lifetime and higher product reliability could be obtained.

If a groove is formed on a semiconductor substrate by a wet-etching process, the semiconductor substrate would be prevented from being damaged physically and chemically. As a result, a reliable structure of a semiconductor device could be provided.

### BRIEF DESCRIPTION OF THE DRAWINGS

FIG. 1 is a plane view illustrating a summarized structure of an acceleration sensor (semiconductor device) according to a preferred embodiment of the present invention.

FIG. 2 is a rear view illustrating a summarized structure of an acceleration sensor (semiconductor device) according to a preferred embodiment of the present invention.

FIG. 3 is a plane view illustrating a mask pattern used for fabricating an acceleration sensor (semiconductor device) according to a preferred embodiment of the present invention.

FIG. 4 is a plane view illustrating an arrangement of piezoresistance elements used for an acceleration sensor (semiconductor device) according to a preferred embodiment of the present invention.

FIG. 5 includes cross-sectional views, taken on line A-A, showing fabrication steps of a piezoresistance element according to a preferred embodiment of the present invention.

FIG. 6 includes cross-sectional views, taken on line A-A, showing fabrication steps of a piezoresistance element according to a preferred embodiment of the present invention.

FIG. 7 includes cross-sectional views, taken on line A-A, showing fabrication steps of a piezoresistance element according to a preferred embodiment of the present invention.

FIG. 8 includes cross-sectional views, taken on line A-A, showing fabrication steps of a piezoresistance element according to a preferred embodiment of the present invention.

FIG. 9 includes cross-sectional views, taken on line A-A, showing fabrication steps of a piezoresistance element according to a preferred embodiment of the present invention.

FIG. 10 includes cross-sectional views, taken on line A-A, showing fabrication steps of a piezoresistance element according to a preferred embodiment of the present invention.

### DESCRIPTION OF THE REFERENCE NUMERALS

10: Acceleration Sensor
12: Beam
14: Mass
18: Piezoresistance Element
106: SOI layer
110: Contact Region
114: Groove
120: Resistance Layer
124a: Polycrystalline Layer
130: Aluminum Wiring

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

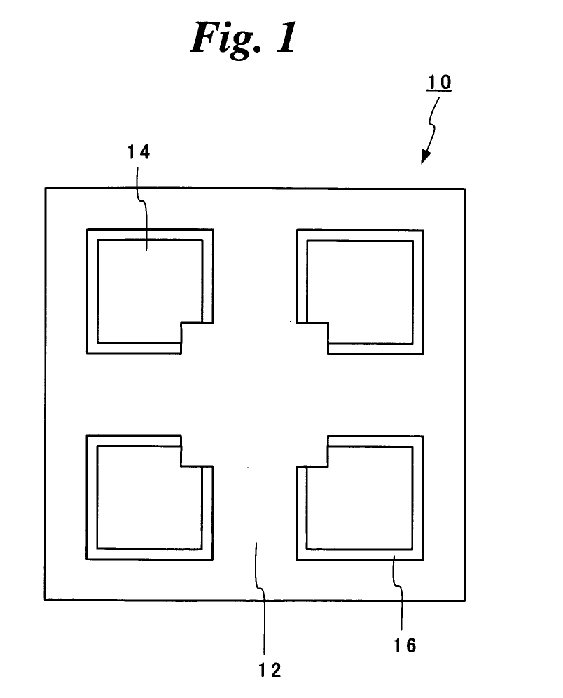

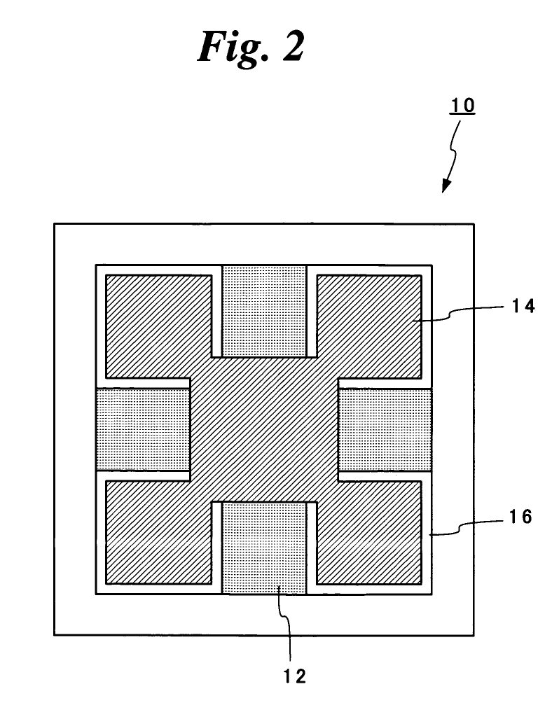

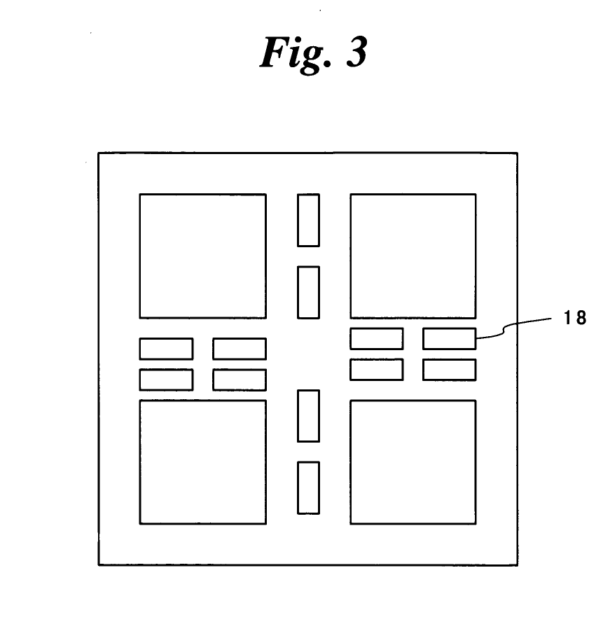

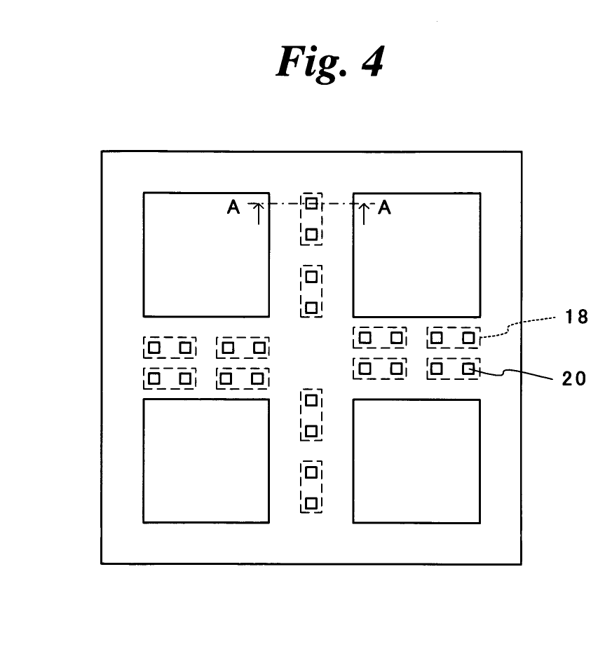

Now, preferred embodiments of the present invention will be described referring to the attached drawings. FIG. 1 is a plane view illustrating a summarized structure of an acceleration sensor (semiconductor device) according to a preferred embodiment of the present invention. FIG. 2 is a rear view illustrating a summarized structure of an acceleration sensor (semiconductor device) according to a preferred embodiment of the present invention. FIG. 3 is a plane view illustrating a mask pattern used for fabricating an acceleration sensor (semiconductor device) according to a preferred embodiment of the present invention. FIG. 4 is a plane view illustrating an arrangement of piezoresistance elements used for an acceleration sensor (semiconductor device) according to a preferred embodiment of the present invention.

A semiconductor device according to the present invention is, for example, applied to a three-dimension acceleration sensor. As shown in FIG. 2, an acceleration sensor 10 includes a mass 14, which is located inside a square frame and supported by beams 12, extending to form a cross shape. In FIG. 2, a reference numeral 16 represents a gap, which is a space formed around the mass 14. The structure of the acceleration sensor 10 will be described in detail later.

As shown in FIGS. 3 and 4, a plurality of piezoresistance elements 18 is formed on the beams 12. Each of the piezoresistance elements 18 is connected to a wiring through contact holes 20. When the mass 14 moves, the piezoresistance elements 18 on the beams are deformed. Changes of resistance values of the piezoresistance elements 18 are detected.

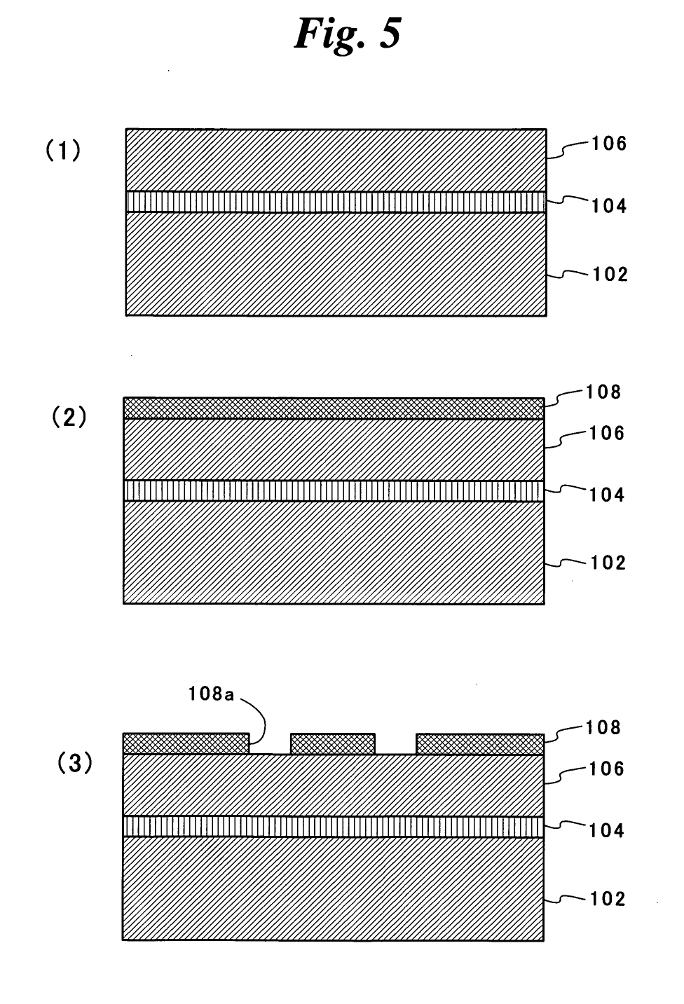

FIGS. 5-10 include cross-sectional views, taken on line A-A, showing fabrication steps of a piezoresistance element 12 according to a preferred embodiment of the present invention. First, as shown in FIG. 5 (1), a SOI wafer is prepared. The SOI wafer includes a silicon substrate 102, a BOX layer 104 and a SOI layer 106 of “n” conductive type. The SOI layer 106 may be of a silicon single crystal substrate having a conductivity of “n” type (100) and a resistance value of 2-3 ω·cm. Next, as shown in FIG. 5 (2), a resist layer 108 is formed on the SOI layer 106. After that, as shown in FIG. 5 (3), openings 108a are formed at areas where pad regions (contact-hole-connection regions) are to be formed.

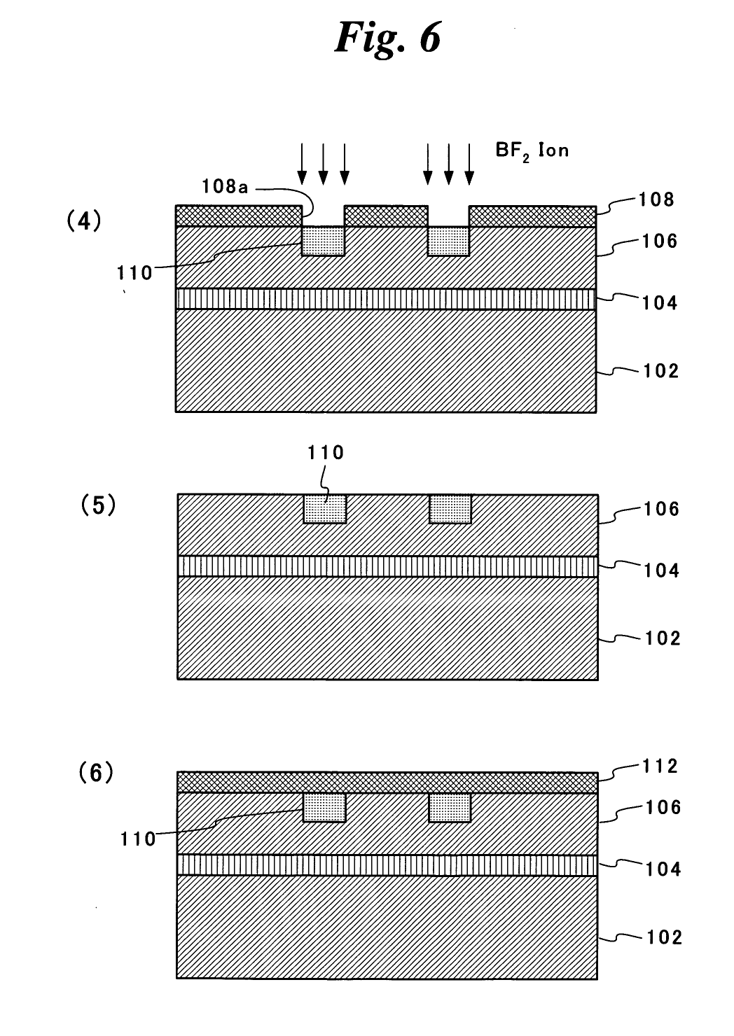

Next, as shown in FIG. 6 (4), BF₂⁺ ions are implanted from the resist openings 108a, for example, under condition of implantation energy of 60 KeV and dose amount of 5×10¹⁵/cm². After that, the substrate is heated at 900° C. (degrees C.) for twenty minutes to form contact regions 110 (P⁺) for piezoresistance elements. After the thermal treatment, as shown in FIG. 6 (5), the resist layer 108 is removed. Next, as shown in FIG. 6 (6), a first oxide silicon layer 112 is formed on the SOI layer 106.

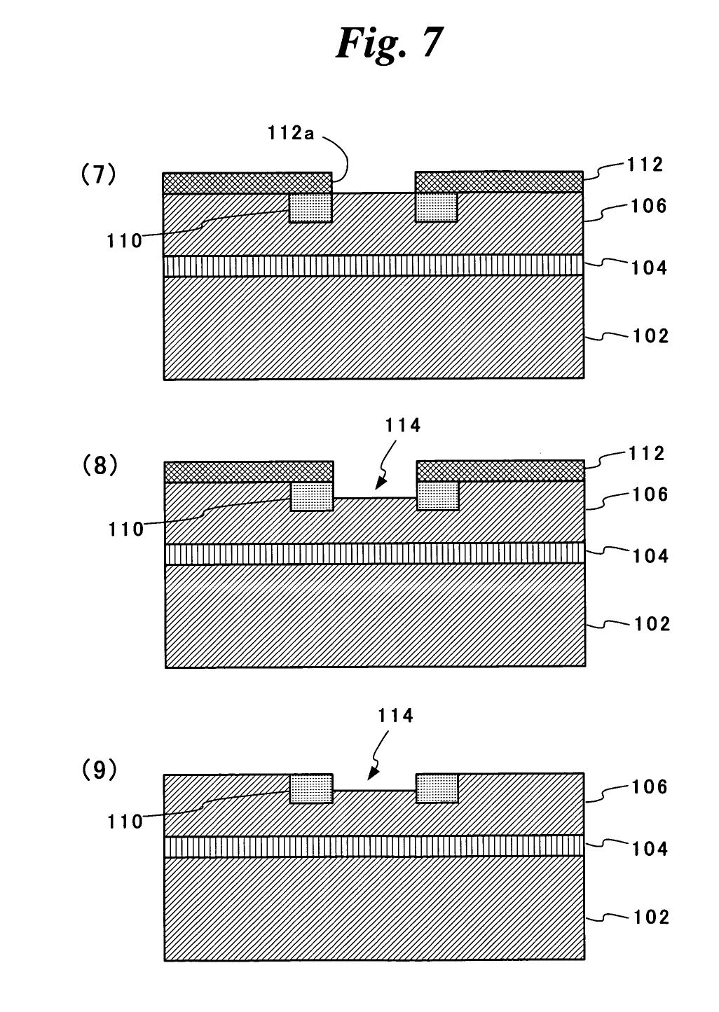

Subsequently, as shown in FIG. 7 (7), openings (apertures) 112a are formed in the first oxide silicon layer 112 at regions where piezoresistance layers to be formed later. Next, as shown in FIG. 7 (8), grooves 114 are formed on the SOI layer 106, exposed in the openings 112a, in a wet-etching process (anisotropy etching) using a KOH solution. The grooves 114 may have a depth of 3000 Å. Here, the word “grooves” may be replaced by other words including “depressions”, “cavities”, “hollows” and “lower place”. After that, as shown in FIG. 7 (9), the first oxide silicon layer 112 is removed.

The groove 114 is located between a pair of contact-hole-connection regions (PAD regions) in a horizontal plane so that at least side surfaces of the PAD regions are exposed. Piezoresistance elements are formed at the contact-hole-connection regions (PAD regions). The contact-hole-connection regions (PAD regions) are formed by an ion implantation process of BF₂⁺under condition in that an implantation energy of 60 KeV, a dose amount of 3×10¹⁵/cm² and an implantation depth of 3000-5000 Å. In general, when a piezoresistance element is formed near the upper most surface of the semiconductor substrate, sensor sensitivity would be higher. Preferably, the grooves 114 are formed to have a depth about 3000 Å, which is near the upper most surface of the substrate, while electrical connection with the PAD regions are secured.

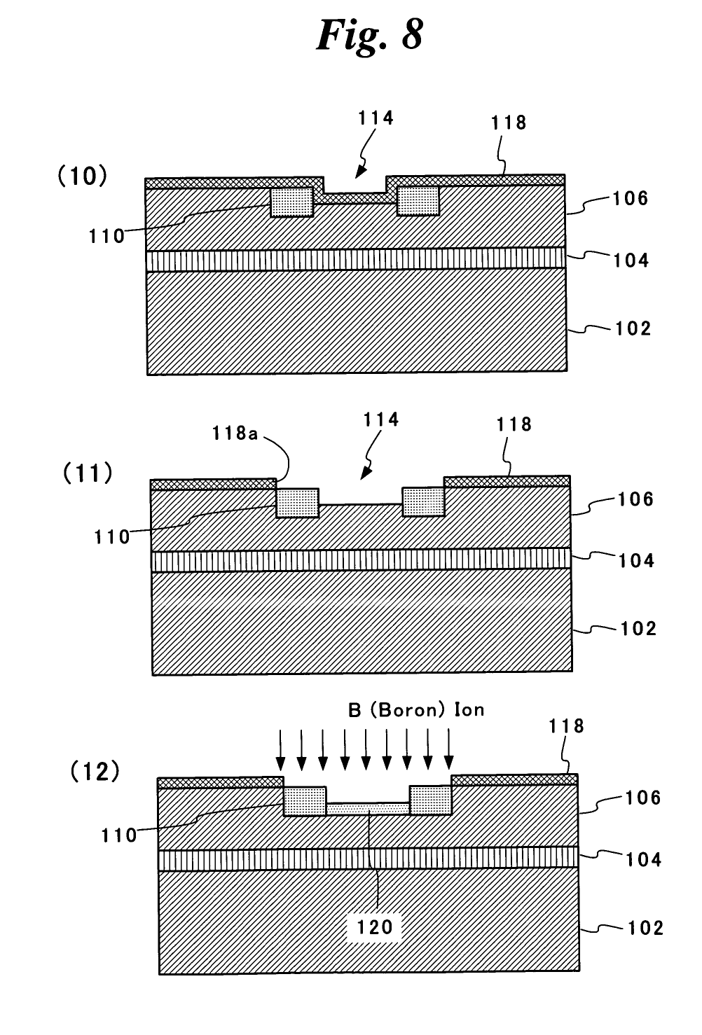

Next, an oxide silicon layer (not shown) is formed as a mask for ion implantation to have a thickness of 100 Å. After that, a resist layer 118 is formed on surfaces of the SOI layer 106, the contact regions 110 and the grooves 114, as shown in FIG. 8 (10). Next, as shown in FIG. 8 (11), an opening 118a is formed on the resist layer 118. The opening 118a is located at areas used for contact holes and piezoresistance elements.

Next, as shown in FIG. 8 (12), boron (B⁺) ions are implanted into the opening 118a through the oxide silicon layer under condition of 30 KeV implantation energy, a dose amount of 5.0×10¹⁴/cm². After that, a thermal treatment of 950° C. (degrees C.) for fifteen minutes is carried out to the substrate to form a piezoresistance element 120. The piezoresistance element 120 in the groove 114 has a conductive type of “p”, which is the opposite of the SOI layer 106. It is possible that the SOI layer 106 has a conductive type of “p” and the piezoresistance element 120 has a conductive type “n”.

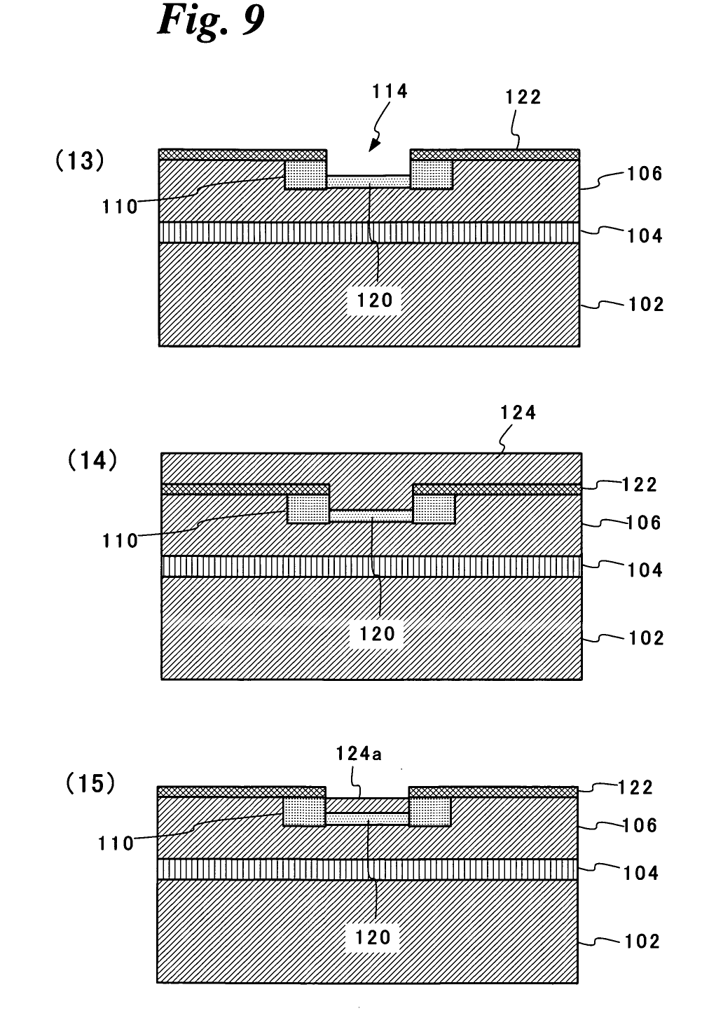

Subsequently, the mask oxide layer is removed and a second oxide silicon layer 122 is formed on the substrate to have a thickness of 1000 Å by a growth method, as shown in FIG. 9 (13), and an opening 114 is again formed at an area where a piezoresistance element is formed. Next, as shown in FIG. 9 (14), a polycrystal silicon layer 124 is formed over the substrate by a deposition process. The polycrystal silicon layer 124 has a resistance value of 2-3 ω(ohm)·m, which is almost the same as the SOI layer 106.

After that, as shown in FIG. 9 (15), an etch-back process is carried out to the polycrystal silicon layer 124 entirely to form a buried silicon layer 124a. Instead of the polycrystal silicon layer 124, which is located on the piezoresistance element 120, a single crystal layer may be formed by an epitaxial method. The buried silicon layer 124a (silicon layer 124) has a conductive type of “n”, which is the same as the SOI layer 106. If the SOI layer 106 has a conductive type of “p”, the buried silicon layer 124a would have a conductive type of “p”.

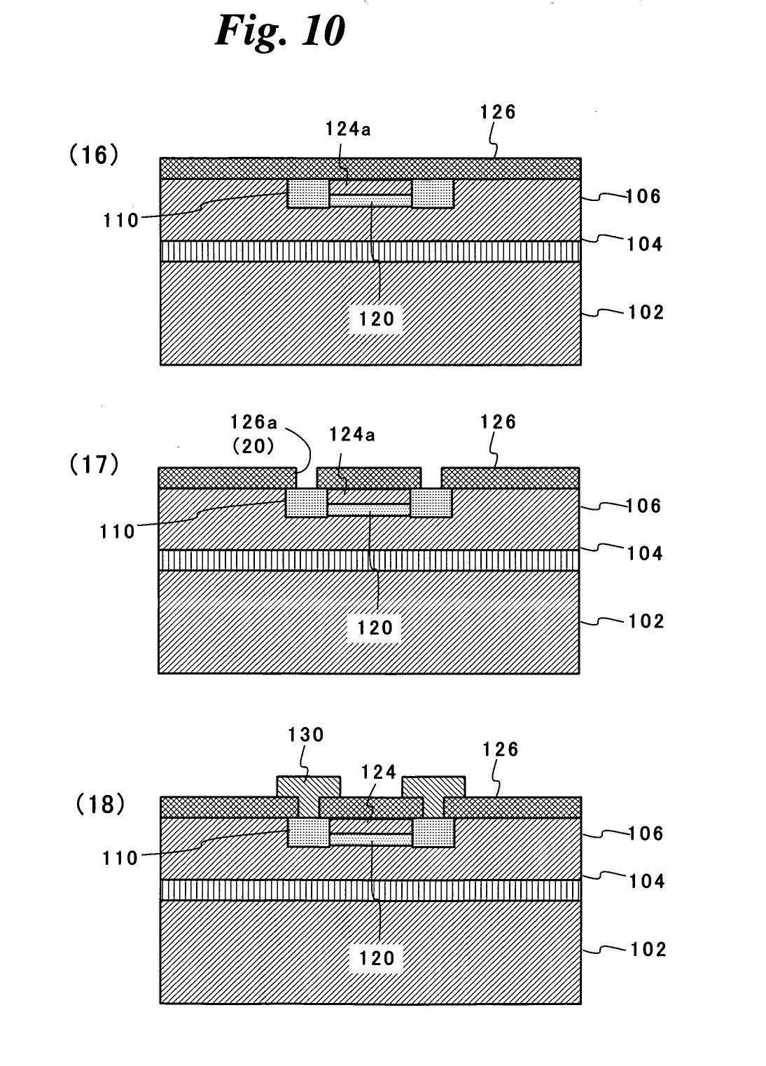

Next, the second oxide silicon layer 122 is removed from the SOI layer 106, and an interlayer insulation layer 126 is formed on the substrate, as shown in FIG. 10 (16). Next, as shown in FIG. 10 (17), contact holes 126a are formed on the interlayer insulation layer 126 so that the contact holes 126a are located above the contact hole connection regions (PAD regions) 110. Subsequently, as shown in FIG. 10 (18), aluminum electrodes 130 are formed in the contact holes 126a by an evaporation process of aluminum and a patterning process. After that, a sintering process is carried out to improve ohmic contact between aluminum and silicon. According to thus described processes, a piezoresistance element is completed.

What is claimed is:

1. A piezoresistance element formed in a semiconductor substrate, comprising:
a pair of contact regions formed in the semiconductor substrate;
a groove formed between the pair of contact regions;
a resistance layer formed in the groove, the resistance layer having a conductive type opposing to the semiconductor substrate; and
a silicon layer formed on the resistance layer, the silicon layer having a conductive type corresponding to the semiconductor substrate.

2. A piezoresistance element according to claim 1, wherein
the silicon layer is of a polycrystal layer.

3. A piezoresistance element according to claim 1, wherein
the resistance layer is a buried impurity-diffusion layer, formed by an ion implantation process of boron (B).

4. A piezoresistance element according to claim 1, wherein
the groove is formed by a wet-etching process.

5. A semiconductor device having a piezoresistance element therein, wherein
the piezoresistance element comprises:
a pair of contact regions formed in the semiconductor substrate;
a groove formed between the pair of contact regions;
a resistance layer formed in the groove, the resistance layer having a conductive type opposing to the semiconductor substrate; and
a silicon layer formed on the resistance layer, the silicon layer having a conductive type corresponding to the semiconductor substrate.

6. A semiconductor device according to claim 5, wherein
the silicon layer is of a polycrystal layer.

7. A semiconductor device according to claim 5, wherein
the resistance layer is a buried impurity-diffusion layer, formed by an ion implantation process of boron (B).

8. A semiconductor device according to claim 5, wherein
the groove is formed by a wet-etching process.
